(19) United States
(12) Patent Application Publication
(10) Pub. No.: US 2025/0183071 A1
(43) Pub. Date: Jun. 5, 2025

(54) INTERFEROMETRY-BASED TEMPERATURE MONITORING IN MANUFACTURING SYSTEMS

(71) Applicant: Applied Materials, Inc., Santa Clara, CA (US)

(72) Inventors: Eric Chin Hong Ng, Milpitas, CA (US); Mehdi Vaez-Iravani, San Jose, CA (US)

(21) Appl. No.: 18/965,974

(22) Filed: Dec. 2, 2024

Related U.S. Application Data
(60) Provisional application No. 63/606,016, filed on Dec. 4, 2023.

(51) Int. Cl. H01L 21/67; G01K 1/02; G01K 3/08; G01K 11/00

(52) U.S. Cl. CPC H01L 21/67248; G01K 1/026; G01K 3/08; G01K 11/00

(57) ABSTRACT

Disclosed systems and techniques are directed to interferometry-based temperature monitoring of various operations performed in manufacturing systems. For example, the disclosed techniques include directing an incident light to a sample and detecting a plurality of interference patterns (IPs) associated with a light departing from the sample. The light departing from the sample can be generated upon interaction of the incident light with the sample. Each IP of the plurality of IPs can be associated with a respective temperature of a plurality of temperatures of the sample. The techniques further include determining, using the plurality of IPs, a temperature difference between a first temperature of the plurality of temperatures and a second temperature of the plurality of temperatures.

### RELATED APPLICATIONS

This application claims the benefit of the U.S. Provisional Patent Application No. 63/606,016, entitled “INTERFEROMETRY-BASED TEMPERATURE MONITORING IN MANUFACTURING SYSTEMS” filed Dec. 4, 2023, the entire contents of which are being incorporated by reference herein.

### TECHNICAL FIELD

This instant specification generally relates to ensuring quality control of materials manufactured in substrate processing systems. More specifically, the instant specification relates to temperature measurements during various stages of the manufacturing process.

### BACKGROUND

Manufacturing of modern materials often involves various deposition techniques, such as chemical vapor deposition (CVD) or physical vapor deposition (PVD) techniques, in which atoms of one or more selected types are deposited on a substrate (wafer) held in low or high vacuum environments that are provided by vacuum deposition chambers. Materials manufactured in this manner may include monocrystals, semiconductor films, fine coatings, and numerous other substances used in practical applications, such as electronic device manufacturing. Many of these applications rely on the purity of the materials grown in substrate processing systems. The need to maintain isolation of the inter-chamber environment and to minimize its exposure to ambient atmosphere and contaminants therein gives rise to various robotic techniques of sample manipulation and inspection. Improving precision, reliability, and efficiency of such robotic techniques presents a number of technological challenges whose successful resolution facilitates continuing progress of electronic device manufacturing. This is especially applicable given that the demands to the quality of chamber manufacturing products are constantly increasing.

### BRIEF DESCRIPTION OF THE DRAWINGS

FIG. 1 illustrates an example interferometry technique for temperature monitoring of samples in manufacturing systems and other applications, in accordance with at least one embodiment.

FIG. 2 illustrates schematically changes in the interference picture caused by changes in the temperature of a sample detected with the example interferometry technique of FIG. 1, in accordance with at least one embodiment.

FIG. 3 illustrates one example of an interferometry-based temperature monitoring system that can be used with sample manufacturing systems, in accordance with at least one embodiment.

FIG. 4 illustrates one example of a manufacturing machine capable of deploying an interferometry-based temperature monitoring system, in accordance with at least one embodiment.

FIG. 5 is a flow diagram of an example method of interferometry-based temperature monitoring in manufacturing systems, in accordance with some embodiments of the present disclosure.

### SUMMARY

In one embodiment, disclosed is a method of temperature monitoring in a manufacturing system, the method including directing an incident light to a sample and detecting a plurality of interference patterns (IPs) associated with a light departing from the sample and generated upon interaction of the incident light with the sample. Each IP of the plurality of IPs is associated with a respective temperature of a plurality of temperatures of the sample. The method further includes determining, using the plurality of IPs, a temperature difference between a first temperature of the plurality of temperatures and a second temperature of the plurality of temperature.

In another embodiment, disclosed is a system that includes a source of light configured to generate an incident light and a focusing optics configured to focus the incident light towards a sample. The system further includes a detection system configured to detect a plurality of IPs in a light departing from the sample and generated upon interaction of the incident light with the sample. Each IP of the plurality of IPs is associated with a respective temperature of a plurality of temperatures of the sample. The system further includes a processing device configured to determine, using the plurality of IPs, a temperature difference between a first temperature of the plurality of temperatures and a second temperature of the plurality of temperatures.

In another embodiment, disclosed is a semiconductor manufacturing system that includes one or more chambers. The semiconductor manufacturing system includes a source of light configured to generate an incident light and a focusing optics configured to focus the incident light towards a sample located in one of the one or more chambers. The semiconductor manufacturing system further includes a detection system configured to detect a plurality of IPs in a light departing from the sample and generated upon interaction of the incident light with the sample. Each IP of the plurality of IPs is associated with a respective temperature of a plurality of temperatures of the sample. The semiconductor manufacturing system further includes a processing device configured to determine, using the plurality of IPs, a temperature difference between a first temperature of the plurality of temperatures and a second temperature of the plurality of temperatures.

### DETAILED DESCRIPTION

Processing operations performed in sample manufacturing systems include material deposition, etching, patterning, chemical or mechanical polishing, and/or various other operations. Different operations can be performed at different temperatures, e.g., some operations can take place at the room temperature, other operations are carried out at temperatures much higher than the room temperature, and some operations can be performed at temperatures much lower than the room temperature, e.g., at cryogenic temperatures. Maintaining a correct temperature, e.g., as prescribed by a specification of a given processing operation, is important for efficient and high-quality sample manufacturing. Uncontrolled variations of temperature, even as small as several degrees, can negatively affect uniformity, thickness, surface quality, cleanliness (presence of defects and impurities), chemical composition, and/or other physical or chemical characteristics of samples. Similarly, accurate knowledge of the temperature is important between different stages of processing, e.g., during cooling of a wafer after plasma-assisted deposition, in preparation of a next stage of processing.

In many situations, temperature monitoring has to be performed without stopping the processing line to preserve an appropriate environment in processing chambers, e.g., using remote temperature measurement techniques, such as pyrometry. A pyrometer detects thermal (e.g., infrared) radiation emitted from inside a processing chamber and estimates the temperature of the radiation based on the amount and the spectrum of the detected radiation. While relatively accurate at high temperatures, pyrometry is much less accurate near or below room temperatures when the amount of infrared radiation falls precipitously. Pyrometry measurements are sensitive to stray radiation coming from other objects. Additionally, pyrometry measurements tend to have a low accuracy if different objects within a target region have different temperatures. For example, a plasma environment in a processing chamber can have one temperature, a wafer exposed to the plasma environment can have a different, e.g., lower, temperature, and a transparent window through which the radiation is escaping can have even lower temperature. Extensive calibration may be required to overcome these difficulties.

Aspects and embodiments of the present disclosure address these and other challenges of the existing remote temperature measurement techniques by providing for systems and techniques that implement interference-based temperature measurements. In some embodiments, temperature changes of semi-transparent or transparent sample (depending on a wavelength of light) can be measured by detecting and tracking changes in an interference pattern that is formed on an array of optical detectors by beams reflected from a top surface and a bottom surface of a sample.

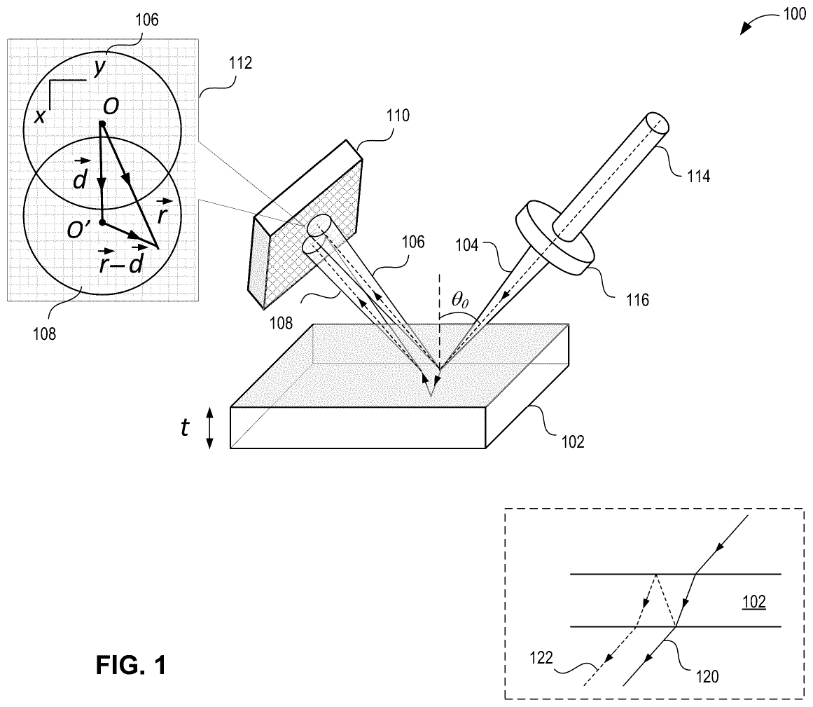

FIG. 1 illustrates an example interferometry technique 100 for temperature monitoring of samples in manufacturing systems and other applications, in accordance with at least one embodiment. A temperature monitoring system directs a focused beam 104 to a sample 102 that reflects at least two beams 106 and 108, e.g., from a top surface of sample 102 and a bottom surface of sample 102, respectively. In particular, reflected beam 108 reflected from the bottom surface of sample 102 of thickness h, travels an extra vertical distance 2h, compared with beam 108 reflected from the top surface. This causes reflected beam 108 to incur an additional phase relative to reflected beam 106:

$${Φ}_{1} = \frac{4 π hn}{λ} cos θ + π , \qquad Eq . ( 1 )$$

where θ is an angle of beam propagation inside the sample (relative to the normal direction), n is the refractive index of a material of sample 102 at the wavelength of light of beams 104, 106, and 108 (with the extra phase shift π caused by reflection of reflected beam 106 from the top surface of sample 102). Correspondingly, sample 102 operates as a Fabry-Perot interferometer with reflected beams 106 and 108 interfering constructively (high reflectance/low transmittance) when phase Φ₁ is an integer number of 2π and interfering destructively when phase Φ₁ is a half-integer number of 2π (low reflectance/high transmittance).

Both the thickness h of sample 102 and the refractive index n can depend on temperature T of sample 102, h=h(T), n=n(T), e.g., as a result of thermal expansion of the crystal lattice of sample 102. For example, silicon displays temperature sensitivity of its refractive index that is of the order, Δn/ΔT≈2×10⁻⁴° C.⁻¹, at a wavelength λ=1300 nm, and its thermal expansion coefficient α=h⁻¹Δh/ΔT≈2.6×10⁻⁶° C.⁻¹. The resulting temperature dependence of the relative phase,

$$\begin{matrix}\frac{d [ {Φ}_{1} ( T ) ]}{d T} = \frac{4 π cos θ}{λ} \frac{d [ h ( T ) n ( T )}{dT} \\ = \frac{4 π cos θ}{λ} ( h ( T ) \frac{d [ n ( T ) ]}{d T} + \frac{d [ h ( T ) ]}{d T} n ( T ) ) ,\end{matrix} \qquad Eq . ( 2 )$$

leads to changes in the interference patterns as temperature T varies. For silicon (as well as for many other materials), the first term in the parenthesis in Eq. (2), which represents the effect of changing temperature on the refractive index, is about two orders of magnitude larger than the second term in Eq. (2), which represents the effect of thermal expansion of the sample:

$${α}^{- 1} \frac{dn}{ndT} \approx 1 {0}^{2} .$$

The dominant first term in Eq. (2) amounts to the variation of the “effective” thickness of sample 102:

$$Δ {h}_{eff} = \frac{h}{n} \frac{d n}{d T} Δ T , \qquad Eq . ( 3 )$$

caused by a change in temperature ΔT. Upon the temperature change ΔT₀,

$$Δ {T}_{0} = {( \frac{d n}{d T} )}^{- 1} \frac{λ}{2 h cos θ} , \qquad Eq . ( 4 )$$

the phase is incremented by ΔΦ₁=ΔT₀ (dΦ₁/dT)=2π and the interference fringes are repeated. For a silicon wafer of thickness h=0.73 mm that is probed with λ=1300 nm light and close to normal light propagation in the wafer, cos θ≈1, the fringes are repeated every ΔT₀≈4.5° C. Correspondingly, observing changes in the fringe patterns enables resolving temperature changes that are at least an order of magnitude (or more) below ΔT₀, e.g., fractions of a degree Celsius, thus providing excellent accuracy of remote temperature monitoring.

The variations of the total reflected light intensity caused by a combination of reflected beams 106 and 108 can be detected by a detection system that includes a detector array 110, e.g., a digital camera or some other multi-pixel imaging device. Utilizing narrow beams, e.g., as illustrated schematically in FIG. 1, allows to resolve (spatially) interference fringes on the imaging plane 112 of detector array 110, which leads to a higher accuracy of temperature change detection. For example, focused incident beam 104 can be generated by focusing an incident beam 114 (e.g., a collimated beam) by one or more elements of focusing optics 116. In one illustrative non-limiting embodiment, incident beam 104 can be a Gaussian beam having at its narrowest point (e.g., on the top surface of sample 102) the profile ˜exp(−r²/w₀²) with a half-width w₀, where r is the radial distance from the axis of incident beam 104. Similarly, the reflected beams 106 and 108 are also Gaussian beams, with the half-width w(z) that increases with the distance z from sample 102, e.g., w²(z)=w₀²+λ²z²/(πw₀)². In particular, the electric field in reflected beam 106 is

$${E}_{1} = E \frac{{w}_{0}}{w ( z )} exp [ - {\vec{r}}^{2} / {w}^{2} ( z ) ] exp [ - ( i k z + \frac{ik {\vec{r}}^{2}}{2 R ( z )} ) ] , \qquad Eq . ( 5 )$$

where k=2π/λ is the central wavevector of the beam and R(z) is the local radius of curvature of its wavefront, e.g.,

$$R ( z ) = z ( 1 + \frac{{π}^{2} {w}_{0}^{4}}{{λ}^{2} {z}^{2}} ) ,$$

and E is the amplitude of reflected beam 106 (on its axis at the narrowest point z=0). The extra phase k\vec{r}²/R(z) is associated with the curved wavefront of the beam.

Similarly, the electric field of the bottom-reflected beam 108 is

$${E}_{2} = {E}^{′} \frac{{w}_{0}}{w ( z )} exp [ - {( \vec{r} - \vec{d} )}^{2} / {w}^{2} ( z ) ] exp [ - ( i k z + \frac{i {k ( \vec{r} - \vec{d} )}^{2}}{2 R ( z )} ) + {Φ}_{1} ] , \qquad Eq . ( 6 )$$

where the wavefront is parallel-shifted by \vec{d}=(d, 0,0) to a distance d that is caused by the beam propagation inside sample 102. (Reflected beam 108 additionally incurs phase Φ₁ given by Eq. (1), as described above.) Distance d is determined by the angle of incidence θ₀ of incident beam 104, e.g., d=2h tan θ cos θ₀, where θ and θ₀ are related by Snell's law, sin θ₀=n sin θ. If imaging plane 112 of detector array 110 is perpendicular to the axes of reflected beams 106 and 108, the distance d also represents the distance between a center O of reflected beam 106 and a center O′ of reflected beam 108, as illustrated by the top-left inset in FIG. 1 The geometric meaning of vectors \vec{r} and \vec{r}−\vec{d} is also illustrated by the inset.

The intensity of reflected light, I=|E₁+E₂|²=I₁+I₂+I_{INT}, measured by detector array 110, includes the sum of two intensities I₁=|E₁|² and I₂=|E₂|² and an interference pattern occurring between reflected beam 106 and reflected beam 108, e.g.,

$${I}_{INT} ( \vec{r} ) = {E}_{1}^{*} {E}_{2} + {E}_{1} {E}_{2}^{*} = 2 A ( \vec{r} ) cos [ {Φ}_{1} + {Φ}_{2} ( \vec{r} ) ] , \qquad Eq . ( 7 )$$

where Φ₂(\vec{r}) is a non-uniform (position-dependent) contribution to the total phase

$${Φ}_{2} ( \vec{r} ) = - \frac{{k ( \vec{r} - \vec{d} )}^{2}}{R ( z )} + \frac{k {\vec{r}}^{2}}{R ( z )} ≡ - \frac{{k ( x - d )}^{2}}{R ( z )} + \frac{k {x}^{2}}{R ( z )} ≡ - \frac{k ( d - 2 x ) d}{R ( z )} , \qquad Eq . ( 8 )$$

arising from the wavefront curvature. The position-dependent amplitude of the interference pattern is

$$A ( \vec{r} ) = \frac{{w}_{0}^{2}}{{w}^{2} ( z )} exp ( - \frac{{( \vec{r} - \vec{d} )}^{2} + {\vec{r}}^{2}}{{w}^{2} ( z )} ) , \qquad Eq . ( 9 )$$

and varies with the radius-vector \vec{r} within the imaging plane 112.

When temperature T of sample 102 is fixed, the interference pattern I_{INT}(\vec{r}), measured by detector array 110, likewise remains constant. As temperature T changes, the uniform phase Φ₁ is modified (e.g., as described above) and shifts the interference pattern I_{INT}(\vec{r}) along the x-axis of the detector array 110 (the x-axis, as drawn in FIG. 1, is parallel to the vector \vec{d} connecting centers of the two reflected beams). Depending on whether temperature T is increasing or decreasing, the interference pattern I_{INT}(\vec{r}) shifts along one or the other direction of the x-axis. More specifically, increasing temperature T leads to an increase in Φ₁. The amount of the shift Δx of the interference pattern I_{INT}(\vec{r}) is determined by the respective compensating decrease in Φ₂(\vec{r}): Δx=−R(z)ΔΦ₁/(2kd). Conversely, decreasing temperature T leads to a shift of the interference pattern I_{INT}(\vec{r}) in the negative direction of the x-axis.

Correspondingly, the direction in which the interference pattern I_{INT}(\vec{r}) shifts can unambiguously identify whether the temperature is increasing (ΔT>0) or decreasing (ΔT<0) and the amount of shift, relative to the detector array 110, can indicate a magnitude of the change ΔT.

Although, for the sake of specificity, the techniques of interferometry-based temperature monitoring are often described as being performed using interference patterns in the reflected light, the same or similar techniques can be used with using interference patterns in a light transmitted through a sample. For example, as shown in the bottom-right inset in FIG. 1, a first transmitted beam 120 can be a beam that experiences a first refraction when entering sample 102 though its top surface and a second refraction when leaving the sample through its bottom surface. A second transmitted beam 122 can be a beam that additionally experiences a first reflection from the bottom surface of sample 102 and a second reflection from its top surface before leaving sample 102 through the bottom surface.

The same, or similar, techniques can be used in samples that include one or more layers of material, e.g., a wafer and one or more films deposited thereon. In some embodiments, a change of phase Φ₁ associated with the propagation of light though such a layered stack can be computed (or simulated) for specific types and thicknesses of materials of the stack or pre-measured and stored as part of calibration data for each of the stacks for which temperature monitoring can be performed. In some instances, the total thickness of the films added to the wafer can be small compared to the total thickness of the wafer. In such instances, a contribution to phase Φ₁ of the films can be ignored or modeled with a temperature-dependent value that is determined using computations, simulations, and/or calibration measurements.

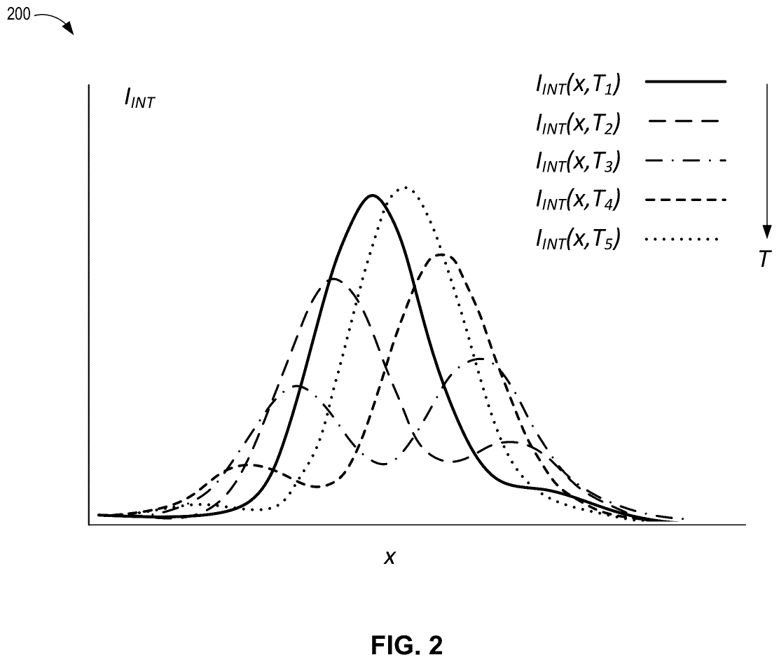

FIG. 2 illustrates schematically changes in an interference picture 200 caused by changes in the temperature of a sample detected with the example interferometry technique of FIG. 1, in accordance with at least one embodiment. Plots in interference picture 200 depict simulated interference patterns I_{INT}(x, T₁), . . . I_{INT}(x, T₅) for five different temperatures of an example wafer, T₁ . . . . T₅. Interference picture 200 corresponds to a fixed field of view of the detector array 110 for z=150 mm and half-width w₀=50 μm. The five individual patterns in FIG. 2 correspond to an appearance of a single pattern moving in the positive direction of the x-axis. Opposite changes of the wafer's temperature result in the motion of the same pattern in the negative direction of the x-axis. The motion of the patterns is accompanied with the changes in the patterns' shapes, as discussed above.

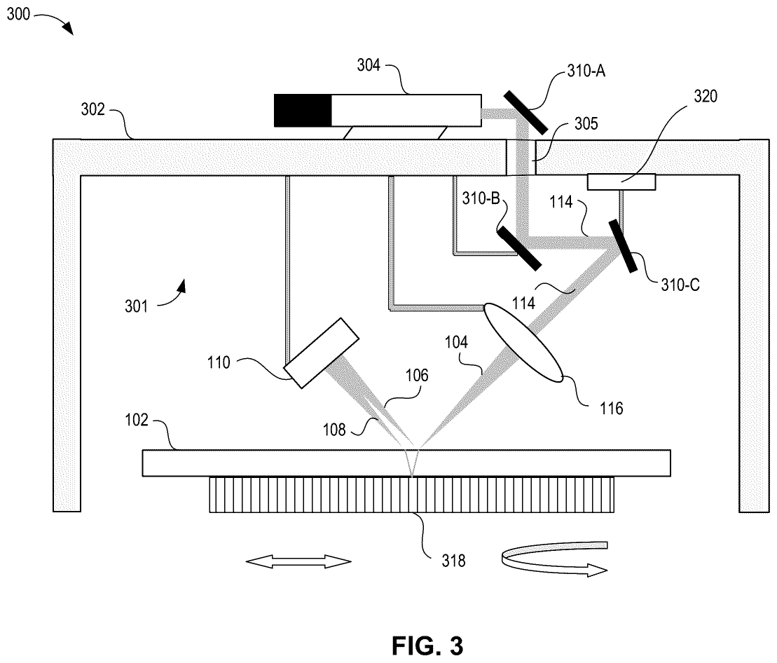

FIG. 3 illustrates one example of an interferometry-based temperature monitoring system 300 that can be used with sample manufacturing systems, in accordance with at least one embodiment. Sample 102 can be located inside a processing chamber 301 having by a housing 302 a portion of which is shown in FIG. 3. Sample 102 can be (or include) a bare wafer, a wafer with one or more films deposited thereon, an unpatterned wafer, an unpolished wafer, a polished wafer, and/or any other type of wafer, substrate, or material. Processing chamber 301 can be used to perform any suitable manufacturing operation pertaining to chemical mechanical polishing (CMP), chemical vapor deposition (CVD), physical vapor deposition (PVD), plasma-enhanced CVD, plasma-enhanced PVD, sputter deposition, atomic layer CVD, combustion CVD, catalytic CVD, evaporation deposition, molecular-beam epitaxy techniques, and/or the like. Processing chamber 301 can use any applicable pressure, including high-vacuum pressure, low-vacuum pressure, atmospheric pressure, above-atmospheric pressure, and/or the like. An environment of processing chamber 301 can be held at any applicable temperature, e.g., above room temperature (including but not limited to plasma environment), room temperature, below room temperature, at or about liquid nitrogen temperature, below liquid nitrogen temperature, and/or the like.

Sample 102 can be illuminated using an illumination system that includes a light source 304 that generates an incident beam 114. In some embodiments, as shown in FIG. 3, light source 304 can be positioned outside housing 302 of processing chamber 301 and the light emitted by light source 304 can be directed into processing chamber 301 through a transparent window 305. Light source 304 can be a pulsed laser, a continuous wave laser, a light-emitting diode, or any other suitable light source. Light source 304 can emit a narrowband light.

In some embodiments, a system of mirrors 310 can be used to direct incident beam 114 along a desired path within processing chamber 301. In some embodiments, the illumination system can include expander optics, collimating optics, and/or other optical elements. The illumination system can further include one or more polarizers, configured to polarize incident beam 114 to a specific target polarization, e.g. s-polarization or p-polarization. The illumination subsystem can be capable of controlling intensity of incident beam 114, e.g., by controlling the cross section of incident beam 114 and/or by controlling the intensity of light outputted by light source 304.

Incident beam 114 can be focused, using focusing optics 116, into focused beam 104 that is directed onto sample 102. Focusing optics 116 can include one or more lenses and/or one or more curved mirrors.

Light reflected from sample 102 can include multiple beams generated upon a corresponding number of reflections of focused beam 104 by two surfaces of sample 102. Reflected beams can be collected using a detection system that includes a detector array 110. Two reflected beams are illustrated in FIG. 3A as being detected by detector array 110—reflected beam 106 that is reflected from the top surface of sample 102 and reflected beam 108 that is reflected from the bottom surface of sample 102—but additional (higher-order) reflected beams can also be collected by detector array 110, in some embodiments.

In some embodiments, the collection system can further include one or more optical elements (not shown in FIG. 3), including objective lenses or curved mirrors, relay optical elements, directional filters, polarizers, and/or other elements. In some embodiments, the collection system can include catadioptric elements. Detector array 110 can deploy complementary metal-oxide-semiconductor (CMOS) image sensors, charge-coupled devices (CCDs), hybrid CMOS-CCD image sensors, photomultiplier tubes (e.g., an array of photocathode-based pixels), photodiodes, phototransistors, 2D imaging cameras, 1D line scanners, multi-cell segmented detectors, or any other suitable photon detectors.

In some embodiments, CMOS image sensors used in detector array 110 can be high-speed and low-noise sensors. For example, CMOS image sensors can have speed at or above 1 Gigapixel per second and noise at 10e or less, e.g., in the range of 2e-5e or even less, in some embodiments.

In some embodiments, the temperature monitoring system 300 can perform temperature measurements for multiple locations on sample 102. In some embodiments, sample 102 can be supported by a movable stage 318 (e.g., robot blade) that can impart translational and/or rotational motion to sample 102 to reposition the illuminated—by the focused beam 104—spot relative to sample 102. In some embodiments, instead of (or in addition to) repositioning of sample 102, the incident beam 114 (and focused beam 104) can be repositioned. For example, an angle of propagation of incident beam 114 can be controlled by changing orientation of mirror 310-C and a parallel translation of incident beam 114 can be achieved by moving a support platform 320 of mirror 310-C, e.g., in the horizontal direction.

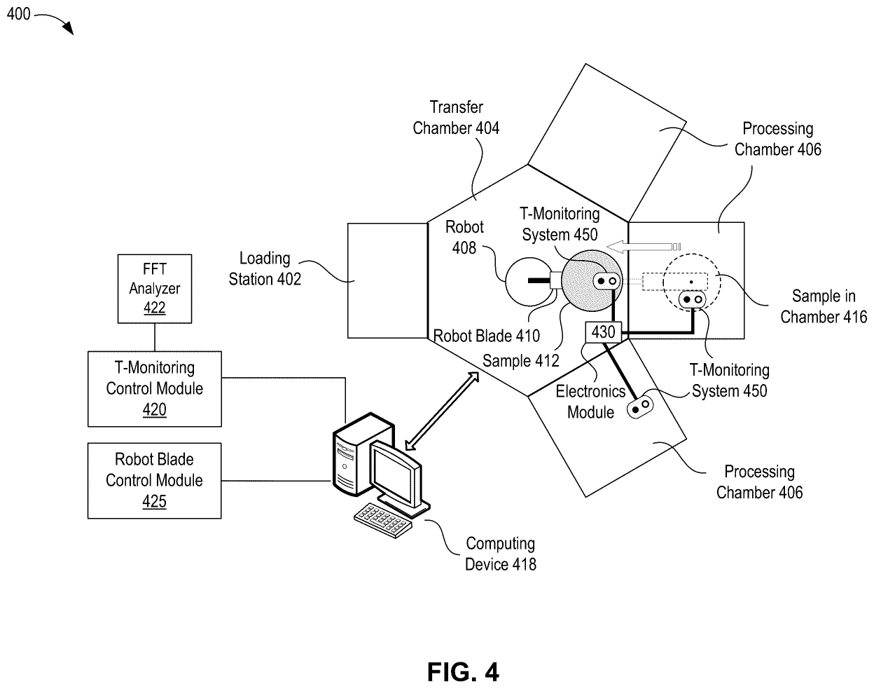

FIG. 4 illustrates one example manufacturing machine 400 capable of deploying an interferometry-based temperature monitoring system, according to one embodiment. In some embodiments manufacturing machine 400 can be a semiconductor manufacturing system. In one embodiment, manufacturing machine 400 includes a loading station 402 (e.g., load-lock chamber), a transfer chamber 404, and one or more processing chambers 406. Processing chamber(s) 406 can be interfaced to the transfer chamber 404 via transfer ports (not shown). The number of processing chamber(s) associated with the transfer chamber 404 need not be limited (with three processing chambers indicated in FIG. 4, as a way of example). Transfer chamber 404 can host a robot 408 operating a robot blade 410 that can support and move a sample 412 (e.g., a wafer, substrate, and/or the like) and/or other movable objects within the manufacturing machine 400. Transfer chamber 404 may be held under pressure (temperature) that is higher or lower than the atmospheric pressure (room temperature). Robot 408 can transfer sample 412 and/or various other products and devices between loading station 402, transfer chamber 404, and any of the processing chambers 406.

In one embodiment, robot blade 410 of robot 408 supports sample 416 when the latter is transferred into one of processing chambers 406. Robot blade 410 can be attached to an extendable arm of robot 408 having a length that is sufficient to reach to different chambers. Sample 412 (and/or sample 416) can be a semiconductor wafer, dielectric wafer, and/or any other object that is transparent (or partially-transparent) that can be placed or transported into one of processing chambers 406, loading station 402, transfer chamber 404, ports connecting transfer chamber 404 to loading station 402 or the processing chambers 406, and/or the like.

Robot blade 410 can deliver (and retrieve) samples to (and from) processing chamber(s) 406 through a slit valve port (not shown) while a lid to processing chamber(s) 406 remains closed. Processing chamber(s) 406 can contain processing gasses, plasma, and various particles used in deposition processes. In some embodiments, a magnetic field can exist inside processing chamber(s) 406. The inside of processing chamber(s) 406 can be held at temperatures and/or pressures that are different from the temperature and/or pressure outside processing chamber(s) 406. Although sample 412 is shown as being supported and moved by robot blade 410 of robot 408, in some embodiments, sample 412 can be transported using a dedicated motion stage or any other suitable movable stage, an existing substrate transfer mechanism, an existing motion mechanism in a process chamber (such as a polishing head or another wafer deployed in a CMP process).

Manufacturing machine 400 can deploy one or more temperature monitoring (T-monitoring) systems 450 operating as disclosed in conjunction with FIGS. 1-3 above. T-monitoring system 450 can include one or more measurement units, each unit having an illumination system, which conditions, directs, and focuses incident light onto a target surface, and a detection system that collects and detects light reflected from the target surface. Some individual measurement units can be located at fixed positions relative to transfer chamber 404, processing chamber(s) 406, and/or any other suitable portion of manufacturing machine 400. Some of the individual units of T-monitoring system 450 can be located fully inside transfer chamber 404, processing chamber(s) 406, and/or the like. Some of the individual units of T-monitoring system 450 can be located fully outside the respective chambers, e.g., directing incident light through a window into the respective chamber(s) and collecting reflected light through the same window or a different window. Some of the individual units of T-monitoring system 450 can be located partially outside and partially inside the respective chamber(s), e.g., directing incident light through a window in the chamber's wall and collecting reflected light using a detector located inside the chamber(s), or vice versa (e.g., using a source of light located inside the chamber(s) but collecting reflected light through a window). In some embodiments, at least some of the individual units of T-monitoring system 450 can be removably mounted on robot blade 410 that is capable of moving the respective unit(s) between various portions of manufacturing machine, e.g., between transfer chamber 404 and one or more of processing chambers 406, loading station 402, and/or the like.

A computing device 418 can set up and control execution of at least some processing operations of manufacturing system 400, such as opening loading station 402, receiving samples in loading station 402, moving the received samples from loading station 402 to transfer chamber 404, equalizing pressures/temperatures between transfer chamber 404 and loading station 402 and/or processing chamber(s) 406, transferring the samples into and/or from processing chamber(s) 406, selecting and carrying out processing operations on the samples in processing chamber(s) 406, transferring processing samples back to loading station 402, and/or performing any other suitable operations. Computing device 418 can include a T-monitoring control module 420 that controls operations of T-monitoring system 450 and a robot blade control module 425 that controls operations of robot blade 410. In one embodiment, T-monitoring control module 420 can receive interference patterns detected by individual units of T-monitoring system 450 and determine temperatures of pertinent samples.

In some embodiments, T-monitoring control module 420 can deploy a Fast Fourier Transform (FFT) analyzer 422 that processes pixelated intensity I(x, y) of the reflected light and identifies position-dependent portion I_{INT}(x, y) of this intensity representative of an interference pattern described in conjunction with FIG. 1. Coordinates x and y can be pixel coordinates associated with detector array 110 (in FIG. 1). In some embodiments, FFT analyzer 422 can use pixels (x, y) as individual FFT points with the number of FFT points coinciding with the number of pixels in detector array 110. In other embodiments, the number of FFT points can be greater than the number of pixels. For example, intensity I(x, y) can undergo an upsampling that introduces one or more additional intensity values between each pair of adjacent pixels, e.g., using various interpolation techniques, such as spline interpolation. When temperature of a sample changes, FFT analyzer 422 can identify a shift Δx between an interference pattern in I_{INT}(x, y; t₁) associated with a current time relative to spatially shifted earlier interference pattern I_{INT}(x, y; t₂) associated with time t₂<t₁, e.g., by identifying a spatial translation I_{INT}(x+Δx, y; t₂) that results in a maximum overlap of the two interference patterns.

In some embodiments, operations of T-monitoring system 450 can be supported by an electronics module 430. Electronics module 430 can include a microcontroller and a memory buffer coupled to the microcontroller. In some embodiments, electronics module 430 can perform at least some processing of the light reflections data, including but not limited to performing FFT computations and identifying changes of temperature of the sample(s). The memory buffer can be used to collect and store data, e.g., a partially or fully processed light reflection data. In some embodiments, the data can be transmitted using a wireless communication circuit. In other embodiments, the data can be transmitted using a wired connection between electronics module 430 and computing device 418. In some embodiments, the data can first be stored (buffered) in the memory buffer prior to being transmitted to computing device 418. In other embodiments, the data can be streamed to computing device 418 as the data is being collected, without being stored in the memory buffer. In some embodiments, the wireless or wired connection can be continuous. In other embodiments, the wireless or wired connection can be established periodically or upon completion of the inspection or some other triggering event, e.g., when a certain minimum change of temperature is detected. Electronics module 430 can further include a power element and a power-up circuit. In some embodiments, the power element can be (or include) a battery. In some embodiments, the power element can be a capacitor. The power element can be rechargeable from a power station. The microcontroller can be coupled to one or more units of T-monitoring system 450. In some embodiments, electronics module 430 can also control at least some operations of robot 408. In some embodiments, electronics module 430 can include an accelerometer to facilitate accurate extension and angular rotation of the robot blade 410 and/or rotation of samples 412 and 416 around samples' axes.

Electronics module 430 can further include a wireless communication circuit, e.g., a radio circuitry for receiving wireless instructions from the computing device 418 and for transmitting light reflection data to computing device 418. For example, the radio circuitry can include an RF front end module and an antenna (e.g., a UHF antenna), which can be an internal ceramic antenna, in one embodiment. The batteries may be of a high temperature-tolerant type such as lithium-ion batteries that can be exposed to a chamber temperature of 450 degrees Celsius for a short time period such as one to eight minutes.

The wireless connection facilitated by the RF front end and antenna can support a communication link between the microcontroller and computing device 418, in some embodiments. In some embodiments, the microcontroller integrated with the robot 408 can have a minimal computational functionality sufficient to communicate information to the computing device 418, where most of the processing of information can occur. In other embodiments, the microcontroller can carry out a significant portion of computations, while the computing device 418 can provide computational support for specific, processing-intensive tasks. Data received by the computing device 418 can include data obtained from the inside of the transfer chamber 404, the processing chambers 406, data collected by T-monitoring system 450, data temporarily or permanently stored in the memory buffer, and so on. The data stored in the memory buffer and/or transmitted to or from the computing device 418 may be in a raw or processed format.

Some components of electronics module 430 can be located on or at the stationary part of the robot 408. For example, the microcontroller, the memory buffer, and the RF front end may be so located. Other components of electronics module 430 can be located on or at the robot blade 410 of the robot 408 and/or individual units of T-monitoring system 450.

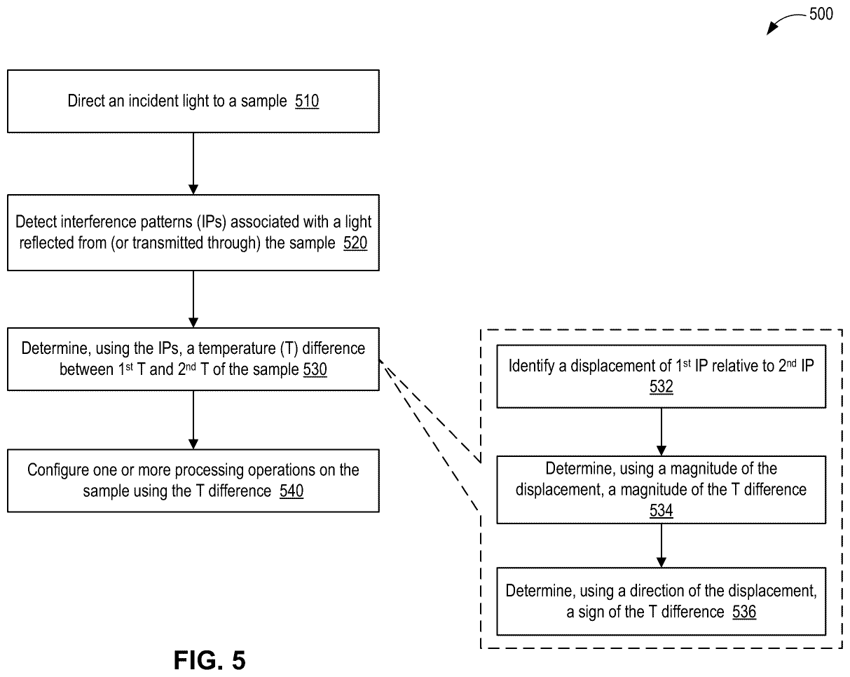

FIG. 5 is a flow diagram of an example method 500 of interferometry-based temperature monitoring in manufacturing systems, in accordance with some embodiments of the present disclosure. In some embodiments, method 500 is performed using systems and components disclosed in conjunction with FIGS. 1-4 or any combination thereof, e.g., temperature monitoring system 300 of FIG. 3 or any suitable combination of such systems and components. In some embodiments, method 500 can be performed by a semiconductor manufacturing system. Performance of method 500 can be supported by various computing devices, e.g., computing device 418 and/or electronic module 430 of FIG. 4. In some embodiments, the computing devices supporting method 500 can deploy one or more processing devices, e.g., central processing units (CPUs), microprocessors, digital signal processors (DSP), application-specific integrated circuits (ASIC), finite-state machines, field-programmable gate arrays (FPGA), and so on, which can be coupled to one or more memory devices (e.g., a random-access memory, a read-only memory, a flash memory, a static memory, and so on). In some embodiments, the processing devices execute software or firmware instructions of method 500 stored in the memory device(s) and/or on any suitable non-transitory computer-readable media. In some embodiments, some of the blocks of method 500 are optional.

Method 500 can be used to determine temperature of any sample in a manufacturing system, including but not limited to a wafer, a substrate, and/or any other suitable transparent or partially transparent target. For example, the disclosed techniques can be applied to any “wafer” or “substrate,” which refers to any material capable of supporting one or more films, masks, photoresists, layers, etc., that are deposited, formed, etched, or otherwise processed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers can be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

At block 510, method 500 can include directing an incident light (e.g., incident beam 114 in FIG. 1) to a sample (e.g., sample 102). In some embodiments, the incident light can be a monochromatic light, e.g., light generated by a laser source. For example, a monochromatic light can have a linewidth that is less than 10 GHz, less than 1 GHz, less than 100 MHz, less than 10 MHz, less than 100 kHz, or less than 10 kHz. In some embodiments, the incident light can include a focused beam (e.g., incident beam 114 conditioned into focused beam 104 by focusing optics 116). In some embodiments, the focused beam can have a Gaussian profile.

At block 520, method 500 can continue with detecting a plurality of interference patterns (IPs) associated with a light departing from the sample. The light departing from the sample can be generated upon interaction of the incident light with the sample. In some embodiments, the light departing from the sample can include a light transmitted through the sample. In some embodiments, the light departing from the sample can include a first reflected beam caused by reflection of the incident light from a first surface of the sample (e.g., reflected beam 106 in FIG. 1) and can further include a second reflected beam caused by reflection of the incident light from a second surface of the sample (e.g., reflected beam 108 in FIG. 1). The plurality of detected IPs can include one or more IPs between the first reflected beam and the second reflected beam (e.g., as illustrated in FIG. 2). The IPs can be detected by measuring the intensity of a superposition of the first reflected beam and the second reflected beam, e.g., I(x, y), where x and y are some coordinates associated with an array of detectors and identifying a position-dependent portion I_{INT}(x, y) of the intensity I(x, y), e.g., by processing the intensity I(x, y) using a Fast Fourier Transform analyzer.

Each IP of the plurality of IPs can be associated with a respective temperature of a plurality of temperatures of the sample. In some embodiments, a first temperature T₁ can be associated with a first time and the second temperature T₂ can be associated with a second time (e.g., that is earlier or later than the first time). In some embodiments, the first temperature can be associated with a first location of the sample and the second temperature can be associated with a second location of the sample (e.g., in situations where the first incident light and the second incident light are incident on different locations of the sample) while the first and the second locations can be probed simultaneously or at different times.

At block 530, method 500 can continue with determining, using the plurality of IPs, a temperature difference ΔT between a first temperature of the plurality of temperatures and a second temperature of the plurality of temperatures, ΔT=T₁−T₂ (or ΔT=T₂−T₁). In some embodiments, determining the temperature difference at block 530 can include operations illustrated in the callout portion of FIG. 5. More specifically, at block 532, method 500 can include identifying a displacement (along one or more spatial axes of a detector array, e.g., x-axis) of the first IP of the plurality of IPs relative to the second IP of the plurality of IPs (e.g., as illustrated in FIG. 2 and further described in conjunction with FIG. 1). At block 534, method 500 can continue with determining, using a magnitude of the displacement, a magnitude of the temperature difference. At block 536, method 500 can include determining, using a direction of the displacement (e.g., a positive or negative direction of the x-axis), a sign of the temperature difference.

At block 540, method 500 may continue with configuring, responsive to the determined temperature difference, one or more processing operations of the manufacturing system. For example, configuring the processing operation(s) can include adjusting temperature of an environment of any portion of the manufacturing system, such, a processing chamber, a transfer chamber, a loading chamber, and/or the like, e.g., by heating or cooling the respective portion, injecting (or removing) hot (or cold) substance (e.g., gas) from the environment of the portion, and/or the like. In some embodiments, configuring the processing operation(s) can include increasing an amount of a backside (heating) radiation incident on a backside of the sample.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplary language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

What is claimed is:

1. A method of temperature monitoring in a manufacturing system, the method comprising:
directing an incident light to a sample;
detecting a plurality of interference patterns (IPs) associated with a light departing from the sample, wherein the light departing from the sample is generated upon interaction of the incident light with the sample, and wherein each IP of the plurality of IPs is associated with a respective temperature of a plurality of temperatures of the sample; and
determining, using the plurality of IPs, a temperature difference between a first temperature of the plurality of temperatures and a second temperature of the plurality of temperatures.

2. The method of claim 1, wherein the incident light comprises a focused beam.

3. The method of claim 2, wherein the focused beam has a Gaussian profile.

4. The method of claim 1, wherein the light departing from the sample comprises:
a first reflected beam caused by reflection of the incident light from a first surface of the sample, and
a second reflected beam caused by reflection of the incident light from a second surface of the sample; and
wherein the plurality of IPs comprises one or more IPs between the first reflected beam and the second reflected beam.

5. The method of claim 1, wherein the first temperature is associated with a first time and the second temperature is associated with a second time.

6. The method of claim 1, wherein the first temperature is associated with a first location of the sample and the second temperature is associated with a second location of the sample.

7. The method of claim 1, wherein determining the temperature difference comprises:
identifying a displacement of a first IP of the plurality of IPs relative to a second IP of the plurality of IPs; and
determining, using a magnitude of the displacement, a magnitude of the temperature difference.

8. The method of claim 7, further comprising:
determining, using a direction of the displacement, a sign of the temperature difference.

9. The method of claim 1, wherein the sample comprises a substrate.

10. The method of claim 9, wherein the sample further comprises one or more films deposited on the substrate.

11. The method of claim 1, wherein the incident light is a monochromatic light.

12. The method of claim 1, wherein the light departing from the sample comprises a light transmitted through the sample.

13. The method of claim 1, further comprising:
configuring, responsive to the determined temperature difference, one or more processing operations of the manufacturing system.

14. A system comprising:
a source of light configured to generate an incident light;
a focusing optics configured to focus the incident light towards a sample;
a detection system configured to detect a plurality of interference patterns (IPs) in a light departing from the sample, wherein the light departing from the sample is generated upon interaction of the incident light with the sample, and wherein each IP of the plurality of IPs is associated with a respective temperature of a plurality of temperatures of the sample; and
a processing device configured to determine, using the plurality of IPs, a temperature difference between a first temperature of the plurality of temperatures and a second temperature of the plurality of temperatures.

15. The system of claim 14, wherein the incident light comprises a focused beam.

16. The system of claim 14, wherein the light departing from the sample comprises:
a first reflected beam caused by reflection of the incident light from a first surface of the sample, and
a second reflected beam caused by reflection of the incident light from a second surface of the sample; and
wherein the plurality of IPs comprises one or more IPs between the first reflected beam and the second reflected beam.

17. The system of claim 14, wherein the first temperature is associated with at least one of:
a first time, or
a first location of the sample, and
wherein the second temperature is associated with at least one of:
a second time, or
a second location of the sample.

18. The system of claim 14, wherein to determine the temperature difference, the processing devices is to:
identifying a displacement of a first IP of the plurality of IPs relative to a second IP of the plurality of IPs.

19. The system of claim 14, wherein the sample comprises a substrate.

20. A semiconductor manufacturing system comprising one or more chambers, the semiconductor manufacturing system comprising:
a source of light configured to generate an incident light;
a focusing optics configured to focus the incident light towards a sample located in one of the one or more chambers;
a detection system configured to detect a plurality of interference patterns (IPs) in a light departing from the sample, wherein the light departing from the sample is generated upon interaction of the incident light with the sample, and wherein each IP of the plurality of IPs is associated with a respective temperature of a plurality of temperatures of the sample; and
a processing device configured to determine, using the plurality of IPs, a temperature difference between a first temperature of the plurality of temperatures and a second temperature of the plurality of temperatures.
